(19) United States
(12) Patent Application Publication
(10) Pub. No.: US 2023/0402632 A1
(43) Pub. Date: Dec. 14, 2023

(54) APPARATUS FOR MONITORING THE CELL VOLTAGE

(71) Applicant: CELLCENTRIC GMBH & CO. KG, Kirchheim/Teck-Nabern (DE)

(72) Inventors: Philipp HAUSMANN, Kirchheim unter Teck (DE); Marc KOELMEL, Kirchheim unter Teck (DE); Benjamin PIECK, Kirchheim unter Teck (DE)

(21) Appl. No.: 18/248,793

(22) PCT Filed: Oct. 14, 2021
(86) PCT No.: PCT/EP2021/078535

§ 371 Date: Apr. 12, 2023

(30) Foreign Application Priority Data
Oct. 15, 2020 (DE) 10 2020 006 353.5

(51) Int. Cl. H01M 8/04537; H01M 8/0202; H01M 8/242; G01R 15/22

(52) U.S. Cl. CPC H01M 8/04552; H01M 8/0269; H01M 8/242; G01R 15/22

(57) ABSTRACT

The invention relates to an apparatus for monitoring the cell voltage of an individual cell (3), formed by a membrane electrode assembly (4) and bipolar plates (6), of a fuel cell stack (1), the apparatus having a measuring device (7) for each of the individual cells (3), which measuring device comprises an optical signal generator (9) which is controllable by the measuring device. The apparatus according to the invention is characterized in that the measuring device (7) is formed on a flexible circuit board that is connected to a frame (5) of a framed membrane electrode assembly (4, 5) or is formed as part of the frame.

The invention relates to an apparatus for monitoring the cell voltage of an individual cell, formed by a membrane electrode assembly and bipolar plates, of a fuel cell stack according to the type defined in more detail in the preamble of claim 1.

The monitoring of the cell voltages of individual cells in a fuel cell stack is known in principle from the prior art. It is often referred to or abbreviated as cell voltage measurement (CVM). In the case of fuel cell stacks, such as are used in vehicles, for example, such a CVM is relatively complex, expensive, and requires a considerable amount of installation space. In addition, the electrical contacts of typically 200 to 400 individual cells per fuel cell stack must be tapped and, if necessary, led out in order to be able to carry out the measurements reliably. Furthermore, the entire structure is arranged in a high-voltage environment and must correspondingly be embodied to be safe, for example with regard to insulation resistance, dielectric strength, and creepage distances. Furthermore, the structure is typically arranged within the housing around the fuel cell stack. Since hydrogen can accumulate here due to permeation and leakage, special explosion protection must be ensured. Furthermore, the entire structure is in a demanding environment in terms of electrochemical corrosion.

In order to master these problems, DE 10 2007 015 735 A1 now proposes an optical cell voltage monitoring device for fuel cell stacks. The optical apparatus is arranged in a measuring device, which is fixed between the bipolar plates of individual cells, in order to generate an optical signal of the measured voltage. These optical signals are then picked up in the manner of an optocoupler by sensors or detectors assigned to the respective signal sources in order to transmit the measured values of the voltages of the individual cells sensed within the fuel cell stack to the external environment of the fuel cell stack. In doing so, high-resolution detectors can be used, wherein the number of detectors can be reduced by using mirrors.

The structure is still relatively expensive and complex, in particular due to the assembly between the bipolar plates and the connection thereto. In addition, high-resolution detectors are required for signal processing, which on the one hand are error-prone and on the other hand are complex and expensive.

The object of the present invention is now to specify an improved apparatus for monitoring the cell voltage according to the preamble of claim 1, which advantageously develops the prior art mentioned.

According to the invention, this object is achieved by an apparatus with the features in claim 1, and here in particular in the characterizing part of claim 1. Advantageous designs and further developments of the apparatus according to the invention result from the dependent claims.

The apparatus according to the invention provides, in a manner similar to that described in the prior art mentioned at the outset, that each individual cell is assigned a measuring device with an optical signal transmitter. According to the invention, the measuring device is formed on a flexible circuit board, which is connected to a frame of a framed membrane electrode assembly, a so-called MEFA (Membrane Electrode Framed Assembly) or is formed as part of the same. This MEFA plays a very crucial role in today's fuel cell stacks. This structure is already completed during the production of the electrodes, the catalytically coated membrane and the gas diffusion layers, which is then provided with its own seal, for example, and then, referred to as SMEFA, is inserted between two bipolar plates when the fuel cell stack is stacked. In the alternative, the seals are correspondingly connected to the bipolar plates or, in principle, are also inserted during stacking. Irrespective of this, a flexible circuit board in the area of the frame is extremely simple and efficient and can also partially form it. Such circuit boards can comprise various functionalities, in the case of the structure according to the invention at least the measuring device with the optical signal generator that can be controlled by it.

This makes the structure extraordinarily simple and very efficient in assembly. The flexible circuit board requires virtually no installation space occupied by other components within the fuel cell stack, so that the apparatus for monitoring the cell voltages of the individual cells can be formed to take up almost no installation space. The use of an optical signal generator, which, as is known in principle from the prior art, interacts with at least one optical sensor in the manner of an optocoupler, also makes it possible to meet the requirements for electrical safety and explosion protection without any problems.

According to an extraordinarily advantageous further development of the apparatus according to the invention, the measuring device can be electrically connected to the two adjacent bipolar plates via flexible conductors and/or particularly preferably via spring contacts. Such a connection via flexible conductors, which form a conductor loop between the flexible circuit board with the measuring device and the bipolar plate, is correspondingly simple and allows the fuel cell stack to expand in length, which is unavoidable during operation, whether due to changing pressures and/or temperatures. The use of spring contacts between the measuring device or the flexible circuit board provided with it and the adjacent bipolar plates allows the same. Furthermore, the variant with the spring contacts is also particularly easy to assemble, since no special attention needs to be paid to contacting the measuring device, but since this occurs automatically when the elements of the fuel cell stack are stacked up, while these are still to be connected, for example soldered, when flexible conductors are used.

The measuring device itself can be formed in a manner known per se. According to a particularly favorable embodiment of the apparatus according to the invention, it comprises in any case a step-up converter. Such a step-up converter is now able to correspondingly step up the relatively low voltage of the individual cells in order to efficiently drive the optical signal generator, which can comprise one or more LEDs, for example. The power is supplied from the respective cell itself, so that no further measures are required to connect the structure.

The cell voltage as a physical input variable for the measuring device is between 0 and typically 1.23 V for each individual cell. Via a corresponding step-up converter, which is preferably formed as part of an integrated circuit, and via a resonant circuit as a clock or frequency generator, this cell voltage, which is typically above 0.6 V, can be stepped up via the step-up converter as a DC/DC step-up converter, for example to a voltage level of 2.4 to 4 V, in order to control the LEDs of the optical signal generator accordingly, in particular multicolor LEDs or several LEDs in different brightness levels, colors, flashing frequencies or the like, all of which can be used in order to receive the voltage of the monitored individual cell without contact, for example via a CCD or CIS sensor, and to evaluate it accordingly for controlling the fuel cell stack.

According to a very advantageous further development of the apparatus according to the invention, the optical signal generator is formed in such a way that it can be controlled by the measuring device in different states, wherein the controllability preferably comprises four different states. A first one of these states, and ideally this is the normal state, can be that the optical signal generator remains switched off. So, if no optical signal is active, the cell works in the specified target range. If there are problems such as too low voltage, which is commonly referred to as low cell, too high voltage (high cell) or even more serious, there is a reversal of the polarity of the individual cell (cell reversal), then the optical signal generator is activated accordingly via the measuring device. The typical voltage for a low cell is less than 600 mV of the individual cell in operation, that of a high cell is more than about 825 mV. A cell reversal occurs when the individual cell delivers −10 mV to −800 mV, usually around −600 mV.

An activated optical signal generator therefore indicates a problem with the respective individual cell and thus actually with the fuel cell stack comprising the individual cell. Ideally, the difference can also be visualized by at least two different states of the optical signal generator when it is switched on, so that the optical signal generator can be used to determine whether the individual cell is working normally, i.e. the optical signal generator is switched off, whether the optical signal generator is switched on because the cell is supplying too much or too little voltage, or whether it is switched on because the individual cell has reversed its polarity, which is also typically referred to as cell reversal. The cell reversal is the most important state to be displayed, followed by the low cells. Excessive voltage, typically referred to as high cell, is the least critical condition.

So the simplest case would be an indication of a problem of whatever kind, followed by the differentiation of the problems into problem and cell reversal, so that the high cells and the low cells are combined in one state or, particularly preferably, the indication of all three states explicitly, if this is easily possible in terms of effort and installation space.

Various possibilities known per se can be used to represent the individual states. For example, in the case of one or more single-color light sources of the optical signal generator, different flashing frequencies or the like can be used to differentiate between the states. However, different colors can be used with particular preference.

According to an extremely favorable design of the apparatus according to the invention, the optical signal generator of each measuring device is formed by a light-emitting diode (LED) which can emit at least two, preferably three, light colors. The light-emitting diode can therefore be formed in particular as a so-called multicolor LED. Depending on the state, it can then remain switched off, which corresponds to the normal state of the individual cell, or it can emit a first color, for example white, which corresponds to a reduced voltage of the individual cell, or red, for example, which would correspond to a reversal of the polarization of the individual cell. Optionally, blue can indicate that the voltage of the individual cell is too high, for example.

In an alternative design, the optical signal generator of each measuring device can have at least two light-emitting diodes. The two or preferably three light-emitting diodes of the optical signal generator can both emit the same color, which, however, requires evaluation via two different optical sensors, or they can also emit different colors according to a particularly advantageous further development of the apparatus according to the invention. In this case, a single optical sensor is basically sufficient if it has the appropriate evaluation electronics, which can distinguish between different light colors generated when multicolor LEDs are used in the optical signal generators, for example by subjecting the recorded signals to a Fourier analysis.

Different light colors can also be generated easily and efficiently using several separately formed LEDs, and depending on the requirements, this can be the simpler and more cost-effective variant than using more complex multicolor diodes, but requires the installation space for several light-emitting diodes, so that one or the other variant can be advantageous depending on the situation.

Irrespective of the two variants, a light is ultimately generated which, when switched on, preferably uses different colors to indicate various problems in the respective individual cell. It is now possible to use corresponding optical sensors to query each individual optical signal generator of the plurality of measuring devices individually or in the manner shown in the prior art described above via a mirror and a high-resolution sensor. In practice, however, it is often completely irrelevant which of the individual cells in a fuel cell stack is causing the corresponding problems, since countermeasures typically have to be taken with a reaction affecting the entire fuel cell stack, or the entire stack has to be switched off, for example, to avoid further damage because switching off individual cells is not possible in practice.

In an extraordinarily favorable and cost-efficient further development of the apparatus according to the invention, the signals of all optical signal generators of the fuel cell stack therefore are connected to at least one optical sensor via at least one light guide. This particularly favorable design of the invention can therefore provide for the use of light guides. In principle, each individual light-emitting diode or each light source of the individual optical signal generators could now be provided with its own light guide, which leads the light out to a common optical sensor or to a small number of optical sensors. However, the structure becomes particularly simple and efficient if at least one strip-shaped light guide is employed, in such a way that, according to an advantageous design of the apparatus according to the invention, the optical signal generators couple their light into one of the longitudinal sides of the strip-shaped light guide and the at least an optical sensor is arranged on at least one of the end faces of this strip-shaped light guide.

A single light guide, which runs along the fuel cell stack in the stacking direction, for example, and in which the optical signal generators of each of the measuring devices control light when they are activated, can then be sufficient, for example, to control all signal generators simultaneously with one single optical sensor. Such a light guide can then be used to detect a problem within the stack with the one optical sensor. If the reaction is a shutdown of the stack, then this is completely sufficient and allows the costs previously incurred for individual cell voltage monitoring to be significantly reduced.

According to an extraordinarily favorable further development of the idea, evaluation electronics can be assigned to the optical sensor, which are set up to distinguish colors. For example, a red light color can be filtered out via a Fourier analysis of the data recorded by the optical sensor if it occurs to the appropriate extent. This means that a single sensor and, if necessary, several active optical signal generators from several individual cells can be used to detect whether one or all of the individual cells suffer from the “low cell” or “high cell” problem or whether one or more of them have a polarization reversal as a problem.

This works both with a single multicolor LED, which can generate different colors, and when using different colored LEDs, both of which radiate their light into one and the same light guide.

An alternative design of the variant with the at least two separate LEDs with preferably different light colors can also provide for at least two strip-shaped light guides are present, which are arranged, for example, in parallel, while the individual LEDs of the optical signal generator are also arranged, for example, side by side and offset transversely to the stacking direction. The light from one LED and the light from the other LED can then be guided into the region of one of the ends of the stack in a targeted manner via two or three light guides running along the stack. Using a sensor for each light guide, one or the other LED and thus one or the other state, i.e. the presence of at least one low cell, one high cell or the presence of at least one cell with reversed polarity can then be detected without complex software analysis.

Depending on the number of individual cells and the length of the fuel cell stack, it can also be advantageous, and this is also possible for the design variant described above with a strip-shaped light guide, for each of the ends of the fuel cell stack, i.e. on two end faces of the light guide, to arrange an optical sensor in order to increase the reliability with low light output in the region of the optical sensors.

Further advantageous designs of the apparatus according to the invention also result from the exemplary embodiment, which is represented in more detail with reference to the figures.

Thereby shows:

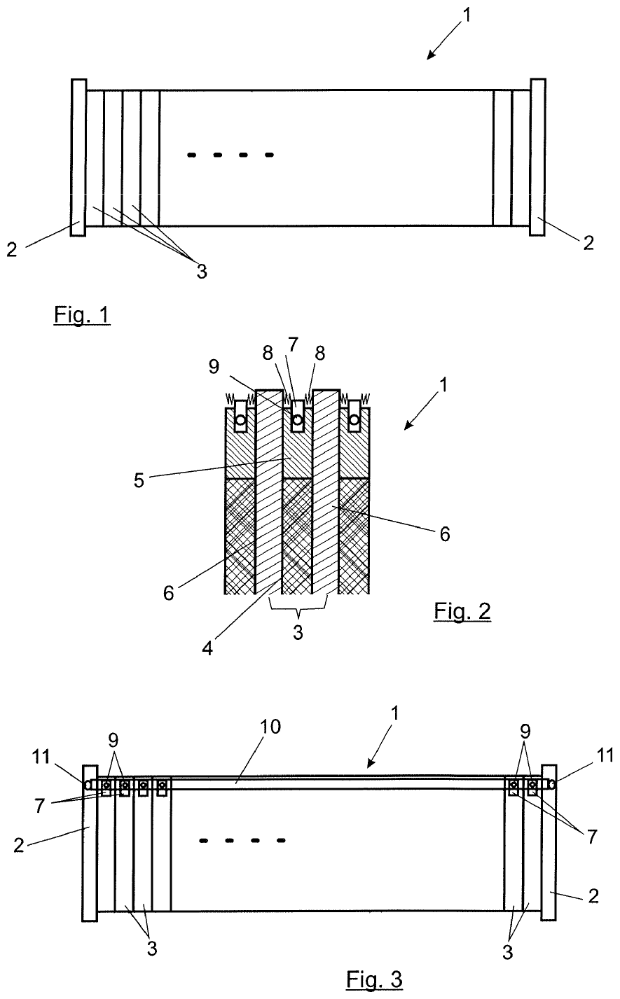

FIG. 1 a schematic representation of a fuel cell stack;

FIG. 2 a section of a fuel cell stack with the apparatus according to the invention;

FIG. 3 a representation analogous to that in FIG. 1 with a particularly favorable design of the apparatus according to the invention;

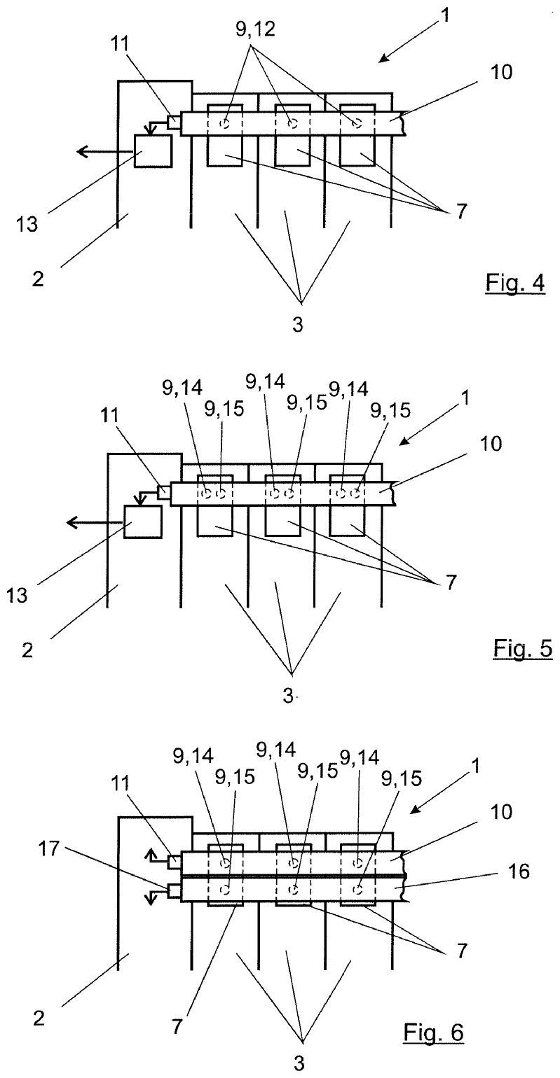

FIG. 4 a representation of a possible design of the apparatus according to the invention based on a section of the fuel cell stack and the apparatus in a first possible embodiment;

FIG. 5 a representation of a possible design of the apparatus according to the invention based on a section of the fuel cell stack and the apparatus in a second possible embodiment;

FIG. 6 a representation of a possible design of the apparatus according to the invention based on a section of the fuel cell stack and the apparatus in a third possible embodiment; and

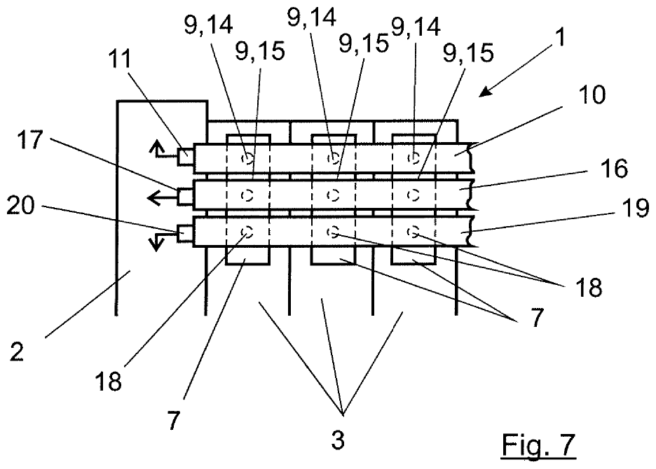

FIG. 7 a representation of a possible design of the apparatus according to the invention based on a section of the fuel cell stack and the apparatus in a fourth possible embodiment.

In the representation of FIG. 1, a fuel cell stack denoted by 1 is shown in very general terms. Between two end plates, each denoted by 2, there is a plurality of individual cells denoted by 3, not all of which are represented here on the one hand and not all of those represented are provided with a reference numeral on the other hand. The structure of such a fuel cell stack 1 is known to a person skilled in the art. The fuel cell stack 1 represented here should be a low-temperature fuel cell with PEM individual cells, i.e. cells with a catalytically coated proton-conducting membrane.

In the representation of FIG. 2, a section of the fuel cell stack is shown in an enlarged representation. The middle individual cell 3 shown here, of which only an upper part is represented, comprises a so-called membrane electrode assembly 4, which comprises the catalytically coated membrane on the one hand and the gas diffusion layers and electrodes on the other hand. This membrane electrode assembly is glued to a frame 5 here. This structure is also referred to as a framed membrane electrode assembly or Membrane Electrode Frame Assembly (MEFA). This MEFA 4, 5 can be provided with its own seals, which are not represented here. It is then referred to as SMEFA. As an alternative to this, the seals can also be inserted when stacked or are arranged in the bipolar plates 6 arranged adjacent to the MEFA 4, 5 in each case. Two of these bipolar plates 6 are represented in the representation of FIG. 2. On one side they have a flow field which is not represented here for distributing hydrogen-containing gases and on the other side a flow field which is not represented here for distributing oxygen-containing gas to the two adjacent individual cells. A flow field for cooling medium is typically arranged in between in the interior of the bipolar plate 6. All of this is known to those skilled in the art of fuel cells. The bipolar plates 6 can be made of metal or of plastics provided with electrically conductive fillers or plastic materials with an electrically conductive coating. All of this is of secondary importance for the present invention, so that it will not be discussed further.

In connection with or as part of the frame 5, a flexible circuit board which is not represented here is formed, which carries a measuring device denoted by 7, which is represented here on the frame 5. This measuring device 7 comprises various components such as a step-up converter and a device for detecting the voltage of the individual cell 3 to whose frame 5 it is connected. The measuring device 7 arranged on the flexible circuit board connected to the frame 5 or formed by it is electrically contacted with the two adjacent bipolar plates 6 preferably via resilient electrical contacts 8, namely on the one side with the positive surface and on the other side with the negative surface of the corresponding bipolar plate 6. As a result, the voltage of the individual cell 3 of the fuel cell stack 1 assigned to it can be monitored via the measuring device 7.

For the operation of the fuel cell stack 1, it is now essential to distinguish between different voltage states. On the one hand, this is the normal state, a state with reduced cell voltage, which is referred to as “low cell,” a state with increased voltage, which is referred to as “high cell,” and a state in which a reversal of the electrical polarity of the individual cell 3 has taken place. This state is often referred to by the term “cell reversal.” For the control of the fuel cell stack 1, it is now of decisive importance whether all of its individual cells 3 are working normally or whether one or more of the individual cells have one of the critical states just described, wherein the low cell and high cell states are not quite as critical as the state of a cell reversal.

The measuring device 7 can now detect these states. In contrast to conventionally structured devices for monitoring the voltage of the individual cells 3 of the fuel cell stack 1, the measuring device 7 of the type described here with the integration on the frame 5 has the advantage that it is installed directly during the production of the cell and not installed later and does not have to be electrically contacted separately. In order to reliably transmit the signal in the area, which is also critical with regard to explosion protection due to possible hydrogen leaks from the fuel cell stack 1, the measuring device 7 has an optical signal generator 9. This optical signal generator 9 can now in particular represent the above-mentioned states of the voltage of the individual cell 3 accordingly, for example by remaining switched off when the voltage is normal and, in the simplest case, by lighting up in one of the other states.

In principle, the signals from the optical signal generator can then be detected and evaluated in the manner known from the prior art, for example via a series of detectors or by deflecting the light to a high-resolution detector. All of this is conceivable in principle, but it is relatively complex in terms of the installation space required and the costs. Frequently, particularly in vehicle applications, it is sufficient if it is known that at least one of the individual cells 3 of the fuel cell stack 1 has a corresponding problem. In this case, a response must be made, in case of doubt by shutting down the entire fuel cell stack 1 or by changing its media supply accordingly.

The simplest variant of the structure is now shown in the representation of FIG. 3 using a fuel cell stack 1 analogous to the one in FIG. 1. The individual cells 3 represented each have the measuring device 7 with the optical signal generator 9. A light guide 10, which is formed as a strip-shaped light guide, for example with the cross-sectional shape of a cuboid, runs in the stacking direction s along the entire fuel cell stack 1, in such a way that the optical signal generators 9 of all measuring devices 7 of all individual cells 3 couple their light laterally into a longitudinal side of the light guide 10. Optical sensors 11 are now arranged on at least one or optionally on two end faces, preferably in the area of the end faces which face the end plates 2 of the fuel cell stack 1 or end in their area. In principle, one optical sensor 11 is sufficient. However, with a correspondingly high number of individual cells 3 and thus a large length of the fuel cell stack 1 in the stacking direction s, it can be advantageous to provide a further optional optical sensor 11 in the area of the second end plate 2 in order to obtain a reliable result even in case only an individual cell 3 generates a signal via its optical signal generator 9 of the measuring device 7, which is relatively far away along the stacking direction s from only one optical sensor 11 and therefore cannot be reliably detected by it.

As already mentioned above, it can now be advantageous if it is known whether the problem of a low cell, a high cell and/or the problem of a cell reversal has been detected via the optical sensor 11. In principle, there are various possibilities for this, which are represented and explained accordingly in the following representations of FIGS. 4 to 7. A section of one of the end plates 2 with three individual cells 3 and their measuring devices 7 is represented in each case.

In the case of the representation in FIG. 4, each of the measuring devices 7 has a light-emitting diode 12 as an optical signal generator 9. This light-emitting diode 12 is formed as a multicolor LED, which can represent different colors. If the voltage of the respective individual cell 3 is normal, it remains switched off. With a low cell, it emits a first color, e.g. yellow, with a high cell, it emits a second color, e.g. blue, and with a cell with reversed polarity, i.e. a cell reversal, it emits a third color, e.g. red. The light emitted and collected by the light guide 10 and guided into the area of the sensor 11 is now received via the one or optionally two optical sensors 11 arranged on the two end plates 2 and evaluated accordingly by evaluation electronics 13. In particular, a Fourier analysis can be carried out in this evaluation electronics 13 in order to analyze different light colors in the light detected by the sensor 11. If the light is only one color, for example if yellow light is present, then the problem of one or more low cells can be reported further via the evaluation electronics 13. If the light contains only red light, the problem of one or more cell reversals could be reported accordingly. If the light contains only blue light, the problem of one or more high cells could be reported further. If the light contains all three light colors, then a corresponding message that both low cells and a cell reversal are present can be forwarded accordingly. With regard to the hardware, this requires the multicolor LED 12 and with regard to the software, a corresponding evaluation in the evaluation electronics 13.

As an alternative or in principle also in addition to different light colors, different flashing frequencies or sequences, i.e. sequences of specific flashing patterns, could also be used here in order to make the different states of at least one of the individual cells 3 in the fuel cell stack 1 detectable via the at least one optical sensor 11.

The structure can be changed in such a way that the multicolor LED 12 can be dispensed with entirely. The structure in FIG. 5, which is to be understood in principle analogously to the representation in FIG. 4, now provides two differently colored diodes 14, 15, for example, for each one of the optical signal generators 9. If there is sufficient installation space, this can be a more cost-effective variant than using a multicolor LED. In this variant, both LEDs 14, 15 of different colors couple their light into the light guide 10 in the same way as described above. The detection via the at least one sensor 11 and the evaluation in the evaluation electronics 13 then take place analogously. The two different LEDs 14, 15 shown here as an example can therefore pass on a total of three states together with the “switched off” state. For example, this can be the normal function where both LEDs 14, 15 are switched off, it can be the problem of a high cell or low cell where one of the LEDs, for example LED 14, is switched on and it can be the problem of a cell reversal where, for example, LED 15 is switched on. Of course, this structure could be correspondingly expanded with a third LED, in order to be able to distinguish between the high cell and low cell states in the signal arriving at the at least one optical sensor 11.

A further variant is also shown in the representation of FIG. 6. Instead of arranging the LEDs 14, 15, for example, adjacent in the stacking direction in each of the measuring devices 7 as optical signal generators, they can also be arranged offset transversely to the stacking direction in such a way that they, as can be seen in the representation of FIG. 6, couple their light into two light guides 10, 16 running parallel. They can be different colors, but LEDs of the same color can be employed as well. In this case, for example, the LEDs 14 shown above in the representation of FIG. 6 indicate a low cell or high cell if they are activated, the LEDs 15 of the optical signal generator 9 arranged in the area of the second light guide 16 in the representation of FIG. 6 below indicate a cell reversal. The problem of low cells can then be indicated directly via the optical sensor 11 in a manner known per se, without the need for further evaluation with regard to the light colors, and passed on to the corresponding control devices, and the problem of one or more cell reversals via an optical sensor 17 on the end face of the other light guide 16 accordingly.

This structure represented in FIG. 6 can now, as has already been described in principle above, be expanded by a third LED 18 in addition to the two LEDs 14, 15, and in this case also correspondingly by a further light guide 19 and a further optical sensor 20. This is represented accordingly in the representation of FIG. 7, which is otherwise to be understood analogously to the representation of FIGS. 4 to 6. With this structure, one of the states of interest could then be indicated in each individual one of the light guides 10, 16, 19.

Overall, the structure of all variants is extremely simple and requires only a few optical sensors 11, 17, 20, which in turn only have to detect the presence of light and possibly the light color, and which do not have any high requirements, for example with regard to a high pixel resolution or the like.

In principle, the structures are suitable for any type of fuel cell stack 1, in particular for PEM fuel cells. They are particularly favorable for vehicle use of such fuel cell stacks 1, since here the conditions relating to the installation space limitation on the one hand and a very strong cost pressure in the assembly and production of the fuel cell stack 1 on the other hand have to be met.

The apparatuses for monitoring the cell voltage in the possible embodiment variants described make this possible in an ideal manner.

1. An apparatus for monitoring the cell voltage of an individual cell, formed by a membrane electrode assembly and bipolar plates, of a fuel cell stack, having a measuring device for each of the individual cells, which comprises an optical signal generator which can be controlled by it,
characterized in that
the measuring device is formed on a flexible circuit board which is connected to a frame of a framed membrane electrode assembly or formed as part of the same.

2. The device apparatus according to claim 1,
wherein
the measuring device is electrically conductively connected to the two adjacent bipolar plates via flexible conductor elements and/or spring contacts.

3. The apparatus according to claim 1,
wherein
the measuring device comprises a step-up converter.

4. The apparatus according to claim 1,
wherein
the optical signal generator is formed in such a way that it can be controlled by the measuring device with at least three different states.

5. The apparatus according to claim 1,
wherein
the optical signal generator of each measuring device is formed by a light-emitting diode, which is set up to emit light in at least two light colors.

6. The apparatus according to claim 1,
wherein
the optical signal generator of each measuring device is formed by at least two light-emitting diodes.

7. The apparatus according to claim 6,
wherein
the at least two light-emitting diodes of each optical signal generator produce different colors of light.

8. The apparatus according to claim 1,
wherein
the optical signal generators of all measuring devices are connected to at least one optical sensor via at least one light guide.

9. The apparatus according to claim 8,
wherein
an evaluation electronics for evaluating the data of the at least one sensor is provided, which is set up to evaluate the detected signals with regard to the occurrence of specific colors and/or flashing frequencies.

10. The apparatus according to claim 6 or 7,
wherein
at least two light guides are provided, which connect the at least two light-emitting diodes of all optical signal generators separately, each with at least one optical sensor.

11. The apparatus according to claim 10,
wherein
the at least one light guide is formed of a strip-shaped light-guiding material which is arranged such that the optical signal generators couple their light into one of the longitudinal sides, wherein the at least one optical sensor is arranged on at least one end face of the light guide.

12. The apparatus according to claim 2,
wherein
the measuring device comprises a step-up converter.

13. The apparatus according to claim 2,
wherein
the optical signal generator is formed in such a way that it can be controlled by the measuring device with at least three different states.

14. The apparatus according to claim 3,
wherein
the optical signal generator is formed in such a way that it can be controlled by the measuring device with at least three different states.

15. The apparatus according to claim 2,
wherein
the optical signal generator of each measuring device is formed by a light-emitting diode, which is set up to emit light in at least two light colors.

16. The apparatus according to claim 3,
wherein
the optical signal generator of each measuring device is formed by a light-emitting diode, which is set up to emit light in at least two light colors.

17. The apparatus according to claim 2,
wherein
the optical signal generator of each measuring device is formed by at least two light-emitting diodes.

18. The apparatus according to claim 3,
wherein
the optical signal generator of each measuring device is formed by at least two light-emitting diodes.

19. The apparatus according to claim 2,
wherein
the optical signal generators of all measuring devices are connected to at least one optical sensor via at least one light guide.

20. The apparatus according to claim 7,
wherein
at least two light guides are provided, which connect the at least two light-emitting diodes of all optical signal generators separately, each with at least one optical sensor.
